(19) United States
(12) Patent Application Publication
(10) Pub. No.: US 2024/0360588 A1
(43) Pub. Date: Oct. 31, 2024

(54) MACROCELL ARCHITECTURAL STRUCTURES FOR HEAT EXCHANGE IN EPITAXIAL GROWTH PROCESSING EQUIPMENT

(71) Applicant: Applied Materials, Inc., Santa Clara, CA (US)

(72) Inventors: Amir H. TAVAKOLI, San Jose, CA (US); Ala MORADIAN, Sunnyvale, CA (US); Shawn Thanhson LE, San Jose, CA (US)

(21) Appl. No.: 18/419,835

(22) Filed: Jan. 23, 2024

Related U.S. Application Data
(60) Provisional application No. 63/461,808, filed on Apr. 25, 2023.

(51) Int. Cl. C30B 25/10; C30B 25/14

(52) U.S. Cl. CPC C30B 25/10; C30B 25/14

(57) ABSTRACT

An epitaxial growth processing chamber with a component having a macrocell support structure configured with interconnecting physical supports that define fluidly-connected pores is described. A component configured for use in an epitaxial growth processing chamber having a macrocell support structure configured with interconnecting physical supports that define fluidly-connected pores is also described. The component is a baseplate, an exhaust cap, an injection ring, an injection cap, a lower reflector, an upper reflector, a lower heat shield, an upper heat shield, a cone reflector, or combinations thereof. In some instances, the component may further include an inlet flow port. In some other instances, the component may further include an inlet flow port, outlet flow port and a fluid flow wall, and optionally a fluid flow baffle, and optionally a reflective surface.

### CROSS-REFERENCE TO RELATED APPLICATIONS

This application claims the benefit of U.S. Provisional Patent Application Ser. No. 63/461,808, filed on Apr. 25, 2023, the entirety of which is herein incorporated by reference.

### BACKGROUND

### Field

Embodiments described herein generally relate to equipment used in the semiconductor manufacturing, and more particularly, to a substrate processing system with macrocell architectural structures for heat exchange.

### Description of the Related Art

Semiconductor substrates are processed for a wide variety of applications, including the fabrication of integrated devices and micro-sized devices. During fabrication, various parameters may affect the functionality of small-sized features formed on the substrate. For example, the temperature uniformity of the substrate or the temperature(s) of processing chamber component(s) may affect the chamber production yield.

In an epitaxial growth processing chamber, which may be utilized to form integrated circuits on a substrate, a set of quartz liners disposed between the substrate edges and the chamber wall provides some measure of thermal shielding for other process chamber components. However, improved temperature control is needed as semiconductor processing advances.

### SUMMARY

An epitaxial growth processing chamber with a component having a macrocell support structure configured with interconnecting physical supports that define fluidly-connected pores. The component also has an inlet fluid flow port that is configured to provide fluid communication between the macrocell support structure and an exterior of the epitaxial growth processing chamber. The component may be a baseplate, an exhaust cap, an injection ring, an injection cap, a lower reflector, an upper reflector, a lower heat shield, an upper heat shield, a cone reflector, or combinations thereof.

A component configured for use in an epitaxial growth processing chamber having a macrocell support structure configured with interconnecting physical supports that define fluidly-connected pores. The component also has an inlet fluid flow port that is configured to provide fluid communication between the macrocell support structure and an exterior of the component. The component may be a baseplate, an exhaust cap, an injection ring, an injection cap, a lower reflector, an upper reflector, a lower heat shield, an upper heat shield, a cone reflector, or combinations thereof.

### BRIEF DESCRIPTION OF THE DRAWINGS

So that the manner in which the recited features of the present disclosure may be understood in detail, a more particular description of the disclosure may be had by reference to one or more embodiments, some of which are illustrated in the appended drawings. It is to be noted, however, that the appended drawings illustrate only one or more of the several embodiments; therefore, the one or more embodiments provided in the Drawings are not to be considered limiting of the broadest interpretation of the detailed scope. Other effective embodiments as may be described in the Detailed Description may be considered part of the envisioned detailed scope.

FIG. 1 is a schematic drawing of a side cross-sectional view of an epitaxial growth processing chamber, according to one or more embodiments.

FIGS. 2A-2F are schematic cross-sectional representations of macrocell support structure configurations, according to one or more embodiments.

FIGS. 3A-3C are schematic drawings of a representative component in a sandwich configuration having alternative fluid flow pathway configurations, according to one or more embodiments.

FIG. 4A is a schematic drawing of a top-down view of an epitaxial growth processing chamber body, according to one or more embodiments.

FIG. 4B is a section view along line AA in FIG. 4A, according to one or more embodiments.

FIG. 5A is a schematic view of an exhaust cap for an epitaxial growth processing chamber, according to one or more embodiments.

FIG. 5B is a sectional view along line BB in FIG. 5A, according to one or more embodiments.

FIG. 6A is a schematic perspective view of an injector ring, according to one or more embodiments.

FIG. 6B is a schematic sectional view along line CC in FIG. 6A, according to one or more embodiments.

FIG. 7A is a schematic perspective view of a reflector, according to one or more embodiments.

FIGS. 7B, 7C, and 7D are each a schematic sectional view along line DD in FIG. 7A, according to one or more embodiments.

FIGS. 8A, 8B, and 8C are schematic perspective, side, and top-down views, respectively, of a heat shield, according to one or more embodiments.

FIGS. 8D and 8E are each a schematic sectional view along line EE in FIG. 8B, according to one or more embodiments.

FIGS. 9A, 9B, and 9C are schematic drawings of a top-down, bottom-up, and side view, respectively, of a cone reflector, according to one or more embodiments.

FIGS. 9D and 9E are each a schematic sectional view along line FF in FIG. 9C, according to one or more embodiments.

In this disclosure, the terms “top”, “bottom”, “side”, “above”, “below”, “up”, “down”, “upward”, “downward”, “horizontal”, “vertical”, and the like do not refer to absolute directions. Instead, these terms refer to directions relative to a nonspecific plane of reference. This non-specific plane of reference may be vertical, horizontal, or other angular orientation.

To facilitate understanding and better appreciation for the described scope, in some instances either identical or associated reference numerals have been used (where possible) to designate identical or similar elements, respectively, that are common in the figures. One of skill in the art may appreciate that elements and features of one embodiment may be beneficially incorporated in one or more other embodiments without further recitation.

### DETAILED DESCRIPTION

In the following disclosure, reference may be made to one or more embodiments. However, one of skill in the art does appreciate that the disclosure is not limited to specifically described embodiments. Rather, any combination of features and elements, whether related to different embodiments or not, is contemplated to implement and practice the one or more embodiments provided by the disclosure. Furthermore, although the one or more embodiments presented in the disclosure may achieve advantages over other possible solutions, the prior art (if existing), and combinations thereof, whether or not a particular advantage is achieved by a given embodiment is not limited by this disclosure. The aspects, features, embodiments, and advantages provided are merely illustrative. These are not considered elements or limitations of the appended claims except where explicitly recited in one or more of the Claims. Likewise, one of skill in the art should not construe a reference to “the disclosure” as a generalization of any disclosed subject matter.

The present disclosure relates to alternative compositions of various components of the epitaxial growth processing chamber that provides improved heat transfer and radiative shielding over prior-known materials and configurations. In the micro-processor fabrication industry there are issues of substrate temperature non-uniformity that may appear during the use of epitaxial growth processing chambers. Non-uniform and out-of-specification temperature(s) may cause a reduction in product yield due to defects in the materials. Insufficient heat removal or transfer away from portions of the processing vessel, especially along portions of the vessel that emit heat, may result in the inability to cool components rapidly after discontinuation of use. Not controlling heat dissipation—permitting too slow of heat loss/gain—may strain components through thermal degradation, which may reduce their operative lifespan. Increased maintenance of the processing chambers reduces overall product yield due to downtime for repair and replacement of components.

Using components including a macrocell support structure, which is a network of interconnecting voids defined by physical supports, is an approach not yet appreciated in the art for dissipation of thermal energy. Using metal, ceramic, or polymer interconnecting physical supports along with supporting plates or internal solid materials provides not only the capability to absorb electromagnetic (EM) energy in the form of light and heat but also to transmit such energy into cooling fluid or the external environment so as to eliminate the energy and reduce heat from being retained in certain components. As well, there are configurations where the interconnecting physical supports and reflective layers redirect EM energy to redistribute energy not absorbed initially by the substrate being processed, thereby saving energy.

Metal, ceramic, and polymer macrocell structures have high permeability and a significant overall pore volume fraction. Integrating or replacing certain components of the process chamber with such architectures is believed to influence not only the energy management of the process chamber but also the effectiveness of the process itself through the ability to remove heat from certain high-energy areas.

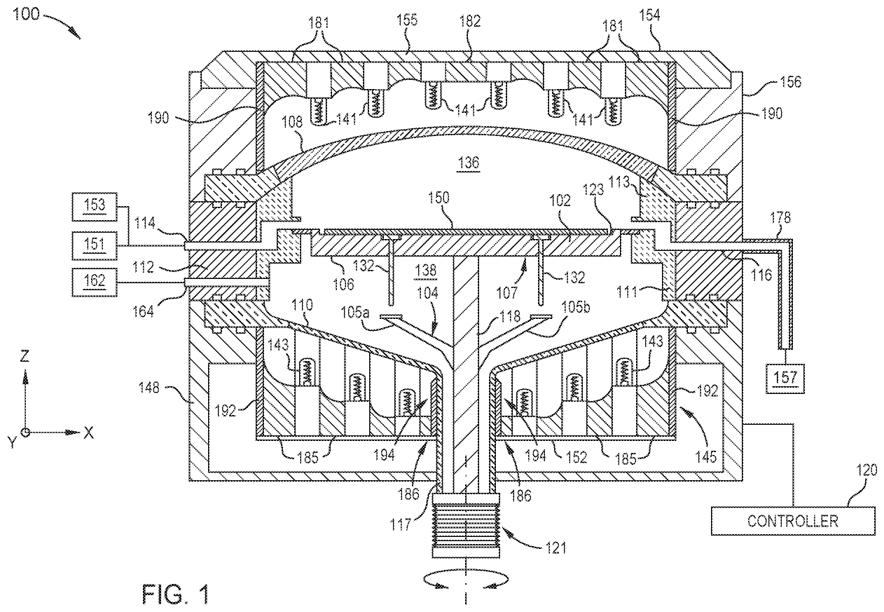

FIG. 1 is a schematic drawing of a side cross-sectional view of an epitaxial growth processing chamber 100. The processing chamber 100 is an epitaxial deposition chamber. Such a processing chamber 100 is utilized to grow an epitaxial film on a substrate 102. The processing chamber 100 creates a cross-flow of precursors across a top surface 150 of the substrate 102.

The processing chamber 100 includes an upper body 156, a lower body 148 disposed below the upper body 156, a baseplate 112 disposed between the upper body 156 and the lower body 148. The upper body 156, the baseplate 112, and the lower body 148 form a chamber body. Positioned within the chamber body are substrate support 106, an upper window 108, such as an upper dome, a lower window 110, such as a lower dome, a plurality of upper lamps 141, and a plurality of lower lamps 143. Lower window 110 also extends downwards with a lower dome shaft 117 through which shaft 118 extends. The baseplate 112 couples the upper body 156 and the lower body 148 together, such as shown in FIG. 1, through upper window 108 and lower window 110, respectively, to from a gas-tight sealed volume. A controller 120 is in communication with the processing chamber 100. The controller is used to control processes and methods, such as the operations of the epitaxial growth processing chamber.

The substrate support 106 is positioned between the upper window 108 and the lower window 110. The substrate support 106 includes a support face 123 that supports the substrate 102.

The plurality of upper lamps 141 is disposed between the upper window and a lid 154. The plurality of upper lamps 141 forms a portion of the upper lamp module 155. The lid 154 includes a plurality of sensors (not shown) for measuring the temperature within the processing chamber 100. The upper window 108 is an upper dome and is formed of an energy transmissive material, such as quartz.

The plurality of upper lamps 141 forms a series of concentric rings, such as two sets, three sets, or more sets of rings of upper lamps 141 as part of the upper lamp module 155. Upper lamp module 155 in FIG. 1 includes several ring-shaped reflectors with concave reflecting surfaces 181 positioned between a pair of two adjacent concentric rings of upper lamps 141 or between a concentric ring of upper lamps 141 and the upper body 156. Upper lamp module 155 includes a reflector with a flat reflective surface 182 positioned between a pair of two adjacent concentric rings or within a ring of upper lamps 141. Each of the concave reflective surfaces 181 and the flat reflective surface 182 has a reflecting surface configured to reflect EM radiation downwards onto a specific area of the substrate 102.

In the process chamber 100, upper lamp module 155 has a heat shield 190 positioned around the outside circumference of the outer-most concentric rings of upper lamps 141. The heat shield 190 has a coating to reflect EM radiation back into the interior of the upper lamp module 155. The heat shield 190 assists in protecting the upper lamp module 155 from rapid temperature changes. The heat shield 190 should provide for gradual temperature increases and declines to reduce thermal shock to the components of the upper lamp module 155, which may extend the operative life span of the components of the upper lamp module 155. The upper lamp module may have more than one heat shield, including a heat shield positioned between each concentric rings of lamp modules. In such instances, each heat shield may be configured to protect the lower portions of the lamp modules in a similar manner.

The plurality of lower lamps 143 are positioned between the lower window 110 and a floor 152 of the processing chamber 100. The plurality of lower lamps 143 form a portion of a lower lamp module 145. The lower window 110 is formed of an energy transmissive material, such as quartz.

The plurality of lower lamps 143 forms a series of concentric rings, such as two sets, three sets, or more sets of rings of lower lamps 143 as part of the lower lamp module 145. Lower lamp module 145 in FIG. 1 includes several reflectors with concave reflecting surfaces 185 positioned between a pair of two adjacent concentric rings of upper lamps 141 or between a concentric ring of lower lamps 143 and the lower body 148. Lower lamp module 145 includes a reflector with a flat reflective surface 186 positioned between a pair of two adjacent concentric rings or within a ring of lower lamps 143. Each reflecting surface 185, 186 have a surface configured to reflect EM radiation upward back into the processing chamber 100.

In processing chamber 100, lower lamp module 145 have a heat shield 192 positioned around the outside circumference of the outer-most concentric rings of lower lamps 143. The heat shield in some instances may have an exterior coating to reflect EM radiation back into the interior of the lower lamp module. The heat shield 192 assists in redirecting energy back into the processing chamber 100, which protects the lower lamp module 145 from rapid temperature changes. The lower lamp module may have more than one heat shield, similar to the upper lamp module.

Lower lamp module 145 in processing chamber 100 also shows a cone reflector 194. Cone reflector 194 is positioned around the outside circumference of the shaft 118 proximate to the inner-most ring of lower lamps 143. The cone reflector 194 is configured on an exterior-facing surface a reflective surface to reflect any EM radiation from the inner-most lower lamps 143 outward and upward. The cone reflector 194 is configured to prevent rapid heat transitions on that portion of the lower window 110 upon operation of the lower lamps 143, which reduces formation of a severe thermal gradient moving up the shaft 118 and the lowest-most portion of the lower window 110 upon activation/deactivation of the lower lamps 143. The cone reflector also reduces cyclic thermal stresses from forming in the material of the lower window, which is often made of quartz, by slowing the heating and cooling processes.

A process volume 136 and a purge volume 138 are defined between the upper window 108 and the lower window 110. The process volume 136 and the purge volume 138 are a portion of a greater internal volume defined at least partially by the upper window 108, the lower window 110, and the one or more liners. The processing chamber 100 includes a lower liner 111 aligned at least partially below the substrate support 106 and an upper liner 113 aligned at least partially above the substrate support 106. The upper liner 113 and lower liner 111 are shown in FIG. 1 positioned along an inner surface of the baseplate 112 to protect the baseplate 112 from the reactive gases introduced and used during deposition operations, cleaning operations, or both.

The internal volume further includes the substrate support 106. The substrate support 106 includes an upwards directed support face 123 onto which the substrate 102 is positioned. The substrate support 106 are coupled or connected to a shaft 118. The shaft 118 is coupled or connected to a motion assembly 121. The motion assembly may include one or more of actuators, adjustment devices, or both, that provide movement, adjustment, or both, for the shaft, the substrate support, or both, within the processing volume.

The substrate support 106 includes one or more lift pin holes 107. The lift pin holes 107 are configured to accommodate a lift pin 132 for lifting of the substrate 102 from the support face 123 of the substrate support 106 either before or after a deposition process is performed. A stop 104 includes a plurality of arms 105a, 105b that each include a lift pin stop onto which the lift pins 132 rest when lowered.

The baseplate 112 includes one or more of gas inlets 114, a one or more of purge gas inlets 164, and one or more gas exhaust outlets 116. The one or more of gas inlets 114 and the one or more of purge gas inlets 164 are positioned on the opposite side of the baseplate 112 from the one or more gas exhaust outlets 116. The gas inlet(s) 114 and the purge gas inlet(s) 164 are each positioned such that a gas flows parallel to the top surface 150 of a substrate 102 positioned within the process volume 136. The gas inlet(s) 114 are fluidly connected to one or more process gas sources 151 and one or more cleaning gas sources 153. The purge gas inlet(s) 164 are fluidly connected to one or more purge gas sources 162. The one or more gas exhaust outlets 116 are fluidly connected to an exhaust pump 157.

One or more process gases supplied using the one or more process gas sources 151 includes one or more reactive gases, such as a silicon-containing gas, a phosphorus-containing gas, and a germanium-containing gas, one or more carrier gases, such as one or more of nitrogen (N₂) and hydrogen (H₂), or combinations thereof. One or more purge gases supplied using the one or more purge gas sources 162 may include one or more inert gases, such as argon (Ar), helium (He), nitrogen (N₂). One or more cleaning gases supplied using the one or more cleaning gas sources 153 may include one or more of hydrogen (H) and chlorine (CI). The one or more process gases may include silicon phosphide (SiP), phospine (PH₃), silane, or combinations thereof. The one or more cleaning gases may include hydrochloric acid (HCl). The epitaxial growth processing chamber is configured to process such materials internally without significant degradation and in the presence of human operators observing normal operation.

The one or more gas exhaust outlets 116 is further coupled or connected to an exhaust cap 178. The exhaust cap 178 is fluidly connect the one or more gas exhaust outlets 116 to the exhaust pump 157. The exhaust cap 178 assists the deposition of a layer on the substrate 102 by regulating pressure differential within the epitaxial growth processing chamber, which impacts the gas flow across the surface of the substrate and therefore the deposition rate. The exhaust cap 178 is positioned on an opposite side of the processing chamber 100 relative to the baseplate 112.

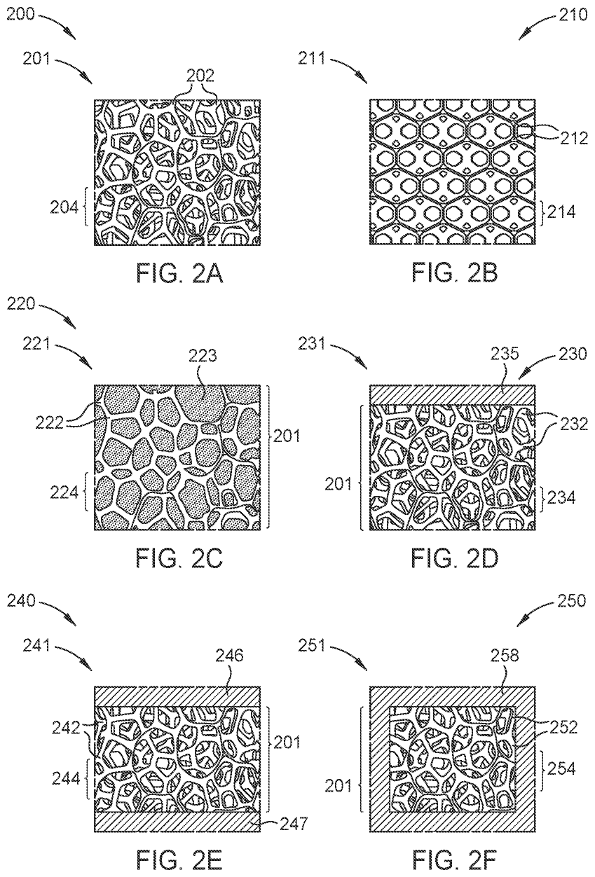

In one or more embodiments, which may be combined with other embodiments, an epitaxial growth processing chamber is configured with one or more components including a macrocell support structure. In one or more embodiments, which may be combined with other embodiments, a component configured for use in an epitaxial growth processing chamber includes a macrocell support structure. Non-limiting examples of such macrocell support structures are provided in FIGS. 2A-2F.

FIGS. 2A-2F are schematic cross-sectional representations of macrocell support structure configurations, according to one or more embodiments. FIG. 2A is a schematic drawing, shown in rectangle 200, of a cross-sectional representation of a free-standing macrocell support structure. A macrocell support structure 201, such as represented in rectangle 200, has interconnecting physical supports 202 that form a three-dimensional (3D) interconnected network; a lattice or a matrix. The spaces or voids in between the interconnecting physical supports 202 define a plurality of voids or pores 204. In instances for an “open” macrocell support structure, at majority (that is, greater than 50%) if not most (that is, greater than 90%) of the pores 204 are fluidly connected to one another, which will be described further, such that a fluid, such as a gas or a liquid, flows in any axial direction through the macrocell support structure 201.

In one or more embodiments, which may be combined with other embodiments, the configuration of the interconnecting physical supports for the macrocell support structure are reticulated, that is in a random or varied configuration, such as represented by the configuration of the interconnecting physical supports 202 for macrocell support structure 201 in FIG. 2A. FIG. 2B is a schematic drawing, shown in rectangle 210, of a cross-sectional representation of a second free-standing macrocell support structure. In one or more embodiments, which may be combined with other embodiments, the configuration of the interconnecting physical supports are in a regular or repeating structure, such as represented in rectangle 210 in FIG. 2B. As seen in macrocell support structure 211, both the interconnecting physical supports 212 and the pores 214 are uniform, repeating, and regularly spread throughout structure. Such a configuration provides predictability not only for fluid flow but also heat transfer given the uniform arrangement of the macrocell support structure.

The interconnecting physical supports provide a much greater degree of internal strength and resistance to deformation. The macrocell support structure is weight-bearing and keeps form under elevated thermal conditions and stress. In one or more embodiments, which may be combined with other embodiments, useful macrocell support structures do not thermally degrade or decompose in a temperature range of from about 0° C. to about 1000° C., such as from about 0 to about 100, 200, 300, 400, 500, 600, 700, 800, 900, and 1000° C., including all range combinations and end points inclusive. To “thermally degrade or decompose” means that a material either undergoes a chemical reaction where chemical bonds are either cleaved between bonded pairs of atoms or a chemical reaction, such as oxidation, occurs that converts the material into another material such that of the resultant material is more likely to lose physical integrity on a macro scale. In one or more embodiments, which may be combined with other embodiments, useful macrocell support structures are configured to be exposed to pressures of 1×10⁵ atmospheres to about 1.5 atmospheres, such as 0.00001, 0.0001, 0.001, 0.01, and 0.1 atmospheres to about 0.2, 0.3, 0.5, 0.7, 0.8, 0.9, 1.0, 1.1, 1.2, 1.3, 1.4, and 1.5 atmospheres of pressure, including all range combinations and end points inclusive. A pressure value less than atmospheric pressure is considered a “partial vacuum”.

In one or more embodiments, which may be combined with other embodiments, the interconnecting physical supports of the macrocell support structure comprise a metal, such as aluminum, aluminum alloys, iron, iron alloys, nickel, nickel alloys, copper, copper alloys, or combinations thereof. An example of a useful aluminum alloy is 6061 aluminum. An example of a useful iron alloy is stainless steel, such as 316L stainless steel. An example of a useful nickel alloy is Hastelloy. An example of a useful copper alloy is brass.

In one or more embodiments, which may be combined with other embodiments, the interconnecting physical supports of the macrocell support structure comprise a ceramic or glass material, such as reticulated vitreous/glassy carbon (RVC); silicon carbide coated RVC; silicon carbide; silicon nitride; quartz, such as black quartz; carbon fiber products, such as carbon fiber fabrics; or combinations thereof.

In one or more embodiments, which may be combined with other embodiments, the interconnecting physical supports of the macrocell support structure comprise a polymer material. In one or more embodiments, which may be combined with other embodiments, the polymer material is a thermoset polymer. In one or more embodiments, which may be combined with other embodiments, the polymer is a thermoplastic material. A polymer that is useful in this type of process is one that has a glass transition temperature (T_{g}) that is greater than about 350° C. In one or more embodiments, which may be combined with other embodiments, the polymer may be a thermoset polymer, poly(ethyl ether ketone) (PEEK), a polyimide, or combinations thereof.

A feature of a macrocell support structure is the size of its pores versus the overall volume of the structure. In one or more embodiments, which may be combined with other embodiments, the macrocell support structure has a void volume or porosity percentage of about 70% to about 98% of the volume of the structure, such as 70, 75, 80, 85, and 90 to about 91, 92, 93, 94, 95, 96, 97, and 98% of the volume of the structure, including all range combinations and end points inclusive.

In one or more embodiments, which may be combined with other embodiments, the average void or pore within the macrocell support structure has a width of about 20 to about 5000 microns, such as 20, 30, 40, 50, 60, 70, 80, 90, 100, 150, 200, 250, 300, 400, 500, 600, 700, 800, 900, 1000, 1250, 1500, 1750, and 2000 to 2250, 2500, 2750, 3000, 3250, 3500, 3750, 4000, 4250, 4500, 4750, and 5000 microns in width, including all range combinations and end points inclusive. “Width” represents a measurable distance between two interconnecting physical supports on opposing sides of a defined void or pore volume shapes, such as a void defined as a repeating cube (opposing diagonal corners) or a sphere (diameter).

The number of pores throughout the structure not only reduces the weight of the components compared to traditional process chamber components but also provides significant thermal flexibility and stress distribution throughout the component. Unlike a more solid part, the component including the macrocell support structure is less likely to fail due to thermal stress caused by a thermal gradients that form during heating and cooling. The macrocell support structure is not only able to distribute stress throughout the interconnected physical supports structure, which is able to bend and twist in reaction to being heated and cooled repeatedly, but the structure is configured to convey thermal energy into any fluid contained within and traversing the pores. The ability to release such stress more easily avoids long-term exposure issues, such as stress-based faults or cracks.

Another feature of a macrocell support structure is permeability. The permeability of the macrocell support structure is what makes the macrocell relatively “open”—openness permits a fluid to flow among the interconnecting physical supports, to receive thermal energy, and to transfer the energy out of the structure, thereby cooling the structure. In one or more embodiments, which may be combined with other embodiments, the macrocell support structure has a permeability of greater than about 70% to 100% permeability, such as greater than about 70, 75, 80, 85, and 90 to about 91, 92, 93, 94, 95, 96, 97, 98, 99, 99.9, 99.99, 99.999, about 100, and 100% permeability, including all range combinations and end points inclusive. The permeability of the macrocell support structure is reflected in the amount of pores that are not fluidly isolated from other pores; that is at least some fluid connectivity between pores that permits fluid to flow from one side of the structure to an opposing or another side of the structure. The permeability among the interconnecting physical supports allows fluids, such as gases, such as nitrogen, argon, helium, other noble gases, and other gases that are generally inert to the material, to either naturally or forcibly flow through the macrocell support structure, such as by using a pressurized fluid or a mass driver, such as a fan or a compressor.

Although in some instances not all of the pores or voids are in fluid communication with other pores, that is, some pores are closed, fluidly isolated, or “dead”, this is not necessarily a flaw or defect in the configuration of the macrocell structure. A lack of permeability for a minority of the pores in the macrocell support structure—“dead” pores—act as limited “heat sinks” by absorbing energy conveyed through the interconnecting physical supports. This permits a degree of slower heating and cooling versus a macrocell support structure form not having such isolated voids or pores. In one or more embodiment, which may be combined with other embodiments, the closed voids are positioned proximate to or in contact with an interior portion of a surface, such as an interior surface of a support panel, a sandwich panel, or a portion of an enclosing surface. Such sealed pores act as a temperature buffer as previously described. The sealed pores also provide additional mechanical coupling or connectivity at a point of coupling or connecting between a surface and the interconnecting physical supports by increasing the amount of material coupling or contacting the surface at the point(s) of interface.

Components that are configured to be useful with the epitaxial growth processing chamber that are at least in part made of the macrocell support structure have one or more physical configurations. FIGS. 2A and 2B, which were previously presented, display cross-sectional representations of free-standing macrocell support structures. In one or more embodiment, a component only includes the macrocell support structure; the component is a free-standing macrocell support structure. Macrocell support structures 201 and 211 each represent a component that does not have any external cladding, mounting, shielding, surface, or protection to block access fluid access into the structure. Unless a surface is surface sealed with a film or layer, a fluid freely traverses through the macrocell support structure unimpeded except for where interconnecting physical supports are present and any portions that contain closed pores.

FIG. 2C is a schematic drawing, shown in rectangle 220, of a cross-sectional representation of a polymer-filled free-standing macrocell support structure. In one or more embodiments, which may be combined with other embodiments, a component is configured such that the component has a free-standing macrocell support structure with pores filled with a second solid material. In such a polymer-filled free-standing macrocell support structure 221 configuration, the second solid material, such as second solid material 223, is contained wholly within pores 224. The second solid material 223 is different than the material of the interconnecting physical supports 222 of the free-standing macrocell support structure 201. In FIG. 2C, rectangle 220 is similar in configuration to the rectangle 200 and the rectangle 210 of FIGS. 2A and 2B, respectively; however, the interior pore structure 224 is completely filled with the second solid material 223. In one or more embodiments, which may be combined with other embodiments, the second solid material is a polymer, such as a thermoset polymer, PEEK, a polyimide, or combinations thereof.

The second solid material of the “solid polymer-filled” configuration should not expand or contract with temperature change at a significantly different rate than the interconnecting physical supports. A significant difference in either the rate or amount of expansion/contraction between the two materials causes physical stress to the macrocell support structure. A significant difference eventually degrades the overall composite structure. The second solid material should also not melt, liquefy, degrade, or decompose under normal or foreseeable operating conditions of the component or the epitaxial growth processing chamber, even at extreme conditions. The second solid material may soften at an elevated temperature, such as thermoset polymers are known to do as they absorb energy and their cross-linked bonds stretch within the polymer matrix; however, the second solid material should not otherwise lose physical integrity of form or swell other than the expected expansion and contraction amount.

FIG. 2D is a schematic drawing, shown in rectangle 230, of a cross-sectional representation of a plate-supported macrocell support structure. In one or more embodiments, which may be combined with other embodiments, a component configured such that the component is in a plate-supported configuration. Rectangle 230 represents a component that is “plate supported”. Support plate 235 in one or more embodiments is coupled to the interconnecting physical supports in plate-supported macrocell support structure of an otherwise free-standing macrocell support structure. In one or more embodiments, which may be combined with other embodiments, the support plate is connected to the interconnecting physical supports. A coupling includes, but is not limited to, an intermediary coupling layer (not shown), such as an adhesive layer, that binds an interior surface of the support plate 235 to exterior contacts along an exterior surface of the macrocell support structure. A connection is made directly through known connective techniques, such as, but not limited to, welding, brazing, diffusion bonding, and mechanical affixation, such as through bolting or clamping.

In one or more embodiments, which may be combined with other embodiments, the parts of a plate-supported component include different materials. For example, the interconnecting physical supports of the macrocell support structure made of a first material and the support plate made of a second material. In one or more embodiments where the plate-supported component includes different materials, which may be combined with other embodiments, the difference in the coefficients of expansion for the different materials of the plate-supported component are within ±10% of one another. Such a composite material reflects many of the benefits that are appreciated for composite materials.

In one or more embodiments, which may be combined with other embodiments, the parts of a plate-supported configuration component include the same material. In instances where the parts of a plate-supported configuration component includes the same material, in one or more embodiments the plate-supported component is a unitary component. That is, there are no seams, separations, gaps, or breaks in between the interconnecting physical supports along the exterior surface of the macrocell support structure where the support plate couples and the support plate that necessitates a coupling or connection; the component is a singular, unified object. Such a component is fabricated using known manufacturing process, such as, but not limited to, additive manufacturing, such as three-dimensional (3D) printing; subtractive manufacturing; compression molding; injection molding; and casting.

In one or more embodiments, which may be combined with other embodiments, the external-facing surface of the support plate has a modified surface. In some instances, the external-facing surface is modified, such as mechanically or chemically, to directly alter its characteristics, such as by scoring, matting, etching, polishing, oxidation, and acid or alkali treatment. In such modifications, the properties of the material including the support plate is enhanced to perform certain functions, such as bonding with another material or reflecting electromagnetic (EM) radiation. In some other instances, the external-facing surface is modified by coupling or connecting an external layer onto the external-facing surface. For example, a reflective film or a mirrored surface is adhered or cladded to the exterior-facing surface to reflect EM radiation. Other such modifications to the exterior-facing surface of the support-plate are appreciated and envisioned.

FIG. 2E is a schematic drawing, shown in rectangle 240, of a cross-sectional representation of a sandwich macrocell support structure. In one or more embodiments, which may be combined with other embodiments, a component is configured such that the component is in a sandwich configuration. Rectangle 240 represents a component that is in a sandwich configuration 241 having a first plate 246 and a second plate 247 positioned on different surfaces of an otherwise free-standing macrocell support structure 201. As shown in FIG. 2E, the plates 246, 247 are positioned opposing one another. However, alternative configurations, have plates positioned not directly across from one another, such as being adjacent to one another. Such a configuration is similar to the plate-supported configuration except there are two or more plates on opposing or different surfaces rather than a single support plate. In one or more embodiments, which may be combined with other embodiments, the first and second plates are coupled or connected to the interconnecting physical supports of the macrocell support structure.

In one or more embodiments, which may be combined with other embodiments, the parts of a component in the sandwich configuration 241 include different materials, e.g., the first plate 246 includes a first material and the second plate 247 includes a second material. In one or more embodiments where parts of the sandwich component include different materials, e.g., the first material and the second material are different, the coefficients of expansion for the different parts of the sandwich component are within ±10% of one another. In one or more embodiments, which may be combined with other embodiments, the parts of a sandwich component include the same material, e.g., the first material and the second material are the same. In instances where the parts of a sandwich component include the same material, e.g., the first plate, the second plate, and the interconnecting physical supports include the same material, the sandwich configured component is a unitary component. In one or more embodiments, which may be combined with other embodiments, one or both of the external-facing surfaces of either or both the first or second plate have a modified surface. An example of such a sandwich configured component includes where the first plate has an external-facing surface that is scored to promote adhesion and the second play has an external-facing surface that is finely polished to reflect EM radiation.

FIG. 2F is a schematic drawing, shown in rectangle 250 of a cross-sectional representation of a surface-sealed macrocell support structure configuration 251. In one or more embodiments, which may be combined with other embodiments, a component is configured such that it is in a surface-sealed configuration. Rectangle 250 represents a component that is in a surface-sealed configuration with an encasing surface 258 surrounding all external sides of an otherwise free-standing macrocell support structure 201. The encasing surface 258 may include a material different from the material of the interconnecting physical supports. Alternatively, the encasing surface 258 may include a material that is the same as the material of the interconnecting physical supports. Such a surface-sealed macrocell support structure configuration 251 does not permit a fluid, such as a gas, liquid, or supercritical fluid, to traverse into or out of the macrocell support structure; rather, the structure and any fluids contained within the pores of the free-standing macrocell support structure 201 are sealed fluidly within the structure. Based upon internal permeability, the fluid moves about within the structure, such as through physical movement of the component or uneven heat distribution. In one or more embodiments, which may be combined with other embodiments, the surface is coupled or connected to the interconnecting physical supports of the macrocell support structure.

In one or more embodiments, which may be combined with other embodiments, the parts of a surface-sealed component include different materials. In one or more embodiments where parts of the surface-sealed component include different materials, the coefficients of expansion for the different parts of the surface-sealed component are within ±10% of one another. In one or more embodiments, which may be combined with other embodiments, the parts of a surface-sealed component include the same material. In instances where the parts of a surface-sealed component include the same material, in one or more embodiments, which may be combined with other embodiments, the surface sealed configuration component is a unitary component. In one or more embodiments, which may be combined with other embodiments, one, some, or all of the external-facing side of the enclosing surface is a modified surface.

When there is a surface-sealed component, the pores of the macrocell support structure are filled with a gas, such as nitrogen, argon, helium, other noble gases, and other gases generally non-reactive with the component, or combinations thereof. The gas within the surface-sealed component is either about at atmospheric pressure or less than atmospheric pressure during processing, as determined at room temperature. This permits the pressure of the gas trapped within the surface-sealed component to rise upon exposure to the heat of the epitaxial deposition process. In one or more embodiments, which may be combined with other embodiments, the pressure of the gas within a surface-sealed component as measured at room temperature is of about 1×10⁵ atmospheres to about 1.0 atmosphere, such as 0.00001, 0.0001, 0.001, 0.01, and 0.1 atmospheres to about 0.2, 0.3, 0.5, 0.7, 0.8, 0.9, and 1.0 atmosphere, including all range combinations and end points inclusive.

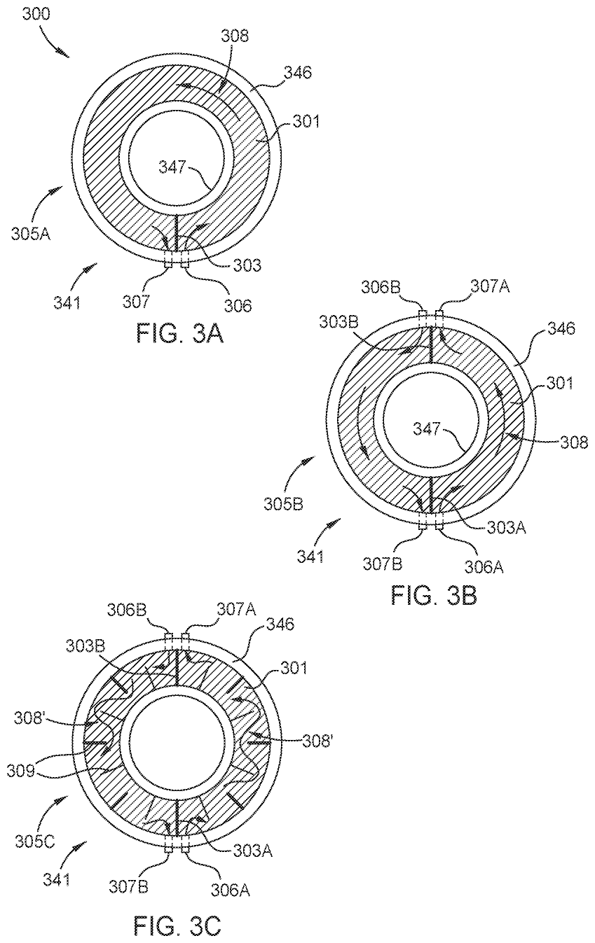

FIGS. 3A-3C are schematic drawings of a representative component 300 in a sandwich configuration having alternative fluid flow pathway configurations. FIG. 3A is a schematic drawing of a first component 305A having a sandwich configuration 341 of a macrocell support structure 301, which is configured similarly to the macrocell support structure 241 of FIG. 2E. In one or more embodiments, which may be combined with other embodiments, a component is configured such that the component has an inlet fluid flow port. In one or more embodiments, which may be combined with other embodiments, a component is further configured to have an outlet fluid flow port paired with an inlet fluid flow port. In both instances, the port configurations provide fluid connectivity to assist in driving a heat transfer fluid through an interior free-standing macrocell support structure. The first component 305A is configured for conveying a heat transfer fluid, such as a gas, through the free-standing macrocell support structure 301 in a single pass. A first plate 346 acts as the exterior wall for the first component 305A, and a second plate 347 acts as the interior wall. An inlet fluid flow port 306 allows the heat transfer fluid to be introduced from the exterior to the macrocell support structure 301 in the interior of the first component 305A. There is also an outlet fluid flow port 307 that permits the opposite: heat transfer fluid passes from the macrocell support structure 301 and egress from the first component. Between inlet fluid flow port 306 and outlet fluid flow port 307 there is a fluid barrier 303 that blocks all fluid flow through the macrocell support structure 301. Any fluid traversing from the inlet fluid flow port 306 to the outlet fluid flow port 307 must do so by torturously flowing along the fluid flow pathway (arrow 308) along the entirety of the interior of macrocell support structure 301.

Effective heat transfer fluids include gases, such as nitrogen, argon, helium, other noble gases, and other gases that are generally inert to the macrocell support structure.

In the macrocell support structure 301, configured similar to the macrocell support structure 201 or the macrocell support structures 211, shown in FIGS. 2A and 2B, respectively, that the heat transfer fluid does not flow in a smooth curve around first component 305A as represented generally by fluid flow pathway (arrow 308). Rather, the heat transfer fluid even in a repeating macrocell support structure 311 will follow a tortuous fluid pathway. The general fluid flow will be from the inlet fluid flow port 306 to the outlet fluid flow port 307. Along the way from the inlet fluid flow port to the outlet fluid flow port, a given quantity of heat transfer fluid will be divided, combined with other fluid, and recombine with the original portion due to the fluid moving in sideflow and downflow direction randomly. In doing so, heat will be absorbed from hot surfaces and heat will be transferred to cooler surfaces. The physical and thermal dynamics and interactions of the heat transfer fluid with the macrocell support structure makes the component an excellent heat transfer device.

The free-standing macrocell support structure in a plate, a sandwich, or an enclosed configuration is cooled by fluid flow. A fluid is introduced through inlet fluid flow port 306, which in the case of the sandwich configuration shown in FIG. 3A, is configured to pass fluid from the exterior of first component 305A to the macrocell support structure 301 within the interior of the first component 305A. Where there is no restrictive barrier on the top and bottom of the macrocell support structure, such as in the plate or sandwich configurations, most of the fluid will find a tortuous fluid flow pathway to egress from the macrocell support structure through pores fluidly connected with the open and non-secured top or bottom facing surfaces.

Alternatively, there may be a fluid flow barrier, such as a gasket, an adjoining surface of the processing chamber, or an enclosing surface, that blocks or at least significantly hinders fluid movement out of the macrocell support structure 301 through the fluidly connected pores at the top or bottom of the macrocell support structure (as one is viewing first component 305A from a top-down vantage point in FIG. 3A). For enclosed configurations, the enclosing surface is that barrier to fluid flow. In other instances, such as the plate or sandwich configuration, such flow barriers are provided by coupling or connecting to other process chamber components. The fluid entering inlet fluid flow port 306 is directed away from fluid flow barrier 303, torturously flows through the fluid flow pathway (arrow 308) present in the macrocell support structure 301 around the first component 305A, and egresses from the first component 305A at outlet fluid flow port 307. In effect, with such a flow configuration, the first component 305A becomes a single pass heat exchanger.

FIG. 3B is a schematic drawing of a second component 305B having a sandwich configuration 341 of the macrocell support structure 301. Second component 305B has a similar configuration as first component 305A, except that second component 305B is configured as a dual single-pass or a “half pass” heat exchanger. A first fluid flow barrier 303A and a second fluid flow barrier 303B disposed on opposing sides of the second component 305B segment the macrocell support structure 301 into two half rings, preventing fluid flow from traversing more than half of the macrocell support structure 301. Each “half” has an inlet fluid flow port (306A/B) and an outlet fluid flow port (307A/B), and are configured such that the heat transfer fluid in the opposing halves flow in contrarian directions relative to one another. Such a configuration is more suited to either maintain a constant temperature on the interior-facing surface of the second plate 347 or for removing heat.

FIG. 3C is a schematic drawing of a third component 305C having a sandwich configuration 341 of the macrocell support structure 301. The third component 305C has a similar configuration as second component 305B, except that the fluid flow pathway (arrow 308′) has been further modified (made even more tortuous) by the inclusion of a plurality of fluid flow baffles 309 among the macrocell support structure 301. The presence of one or more fluid flow baffles increases the effective length of the fluid flow pathway (arrow 308′) by forcing the heat transfer fluid in part to traverse approximately normal to the general fluid flow direction for some of its fluid flow path. Forcing the heat transfer fluid to flow normal to a general flow direction increases the tortuous nature of the fluid flow and the residence time of the heat transfer fluid within the component. Fluid flow baffles 309 also causes more of the heat transfer fluid to more likely contact the interior-facing surfaces of both first plate 346 and second plate 347 by reducing “flow channeling” in the center of the macrocell support structure. Such a flow dynamic would result in the heat transfer fluid absorbing more heat against the hotter surface and transferring the heat to the cooler surface more effectively.

In one or more embodiments, which may be combined with other embodiments, a component further includes an inlet fluid flow port. The inlet fluid flow port is configured to provide fluid communication between the macrocell support structure and an exterior of the component. In one or more embodiments, which may be combined with other embodiments, a component further includes an outlet fluid flow port. The outlet fluid flow port is configured to provide fluid communication between the macrocell support structure and an exterior of the component. In one or more embodiments, which may be combined with other embodiments, a component further includes a fluid flow barrier. In one or more embodiments, which may be combined with other embodiments, a component further includes a fluid flow baffle.

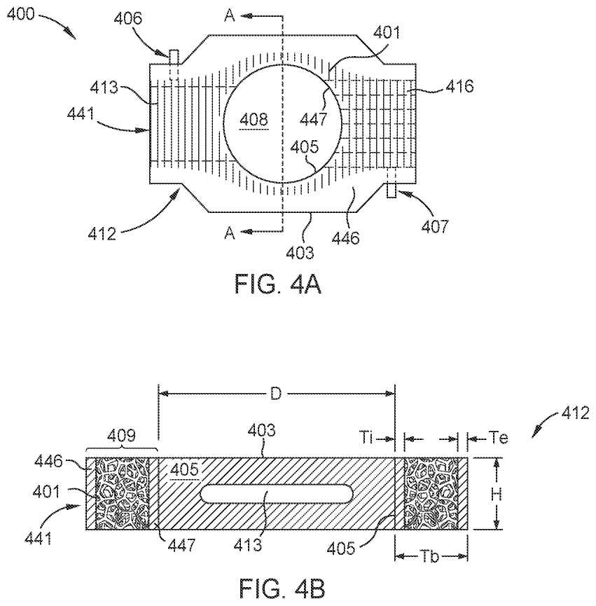

FIG. 4A is a schematic drawing 400 of a top-down view of an epitaxial growth processing chamber body. FIG. 4B is a section view along line AA in FIG. 4A. Epitaxial baseplate 412 is of similar configuration to the baseplate 112 of processing chamber 100 in FIG. 1. FIG. 4B reveal view is directed towards the side of the baseplate 412 defining the substrate slot 413 and away from the one or more gas exhaust outlets 416. In FIGS. 4A and 4B, baseplate 412 is shown with several features, including substrate slot 413, an exterior surface 403, and an interior surface 405 that define the physical bounds of the baseplate 412. Interior surface 405 also defines a cylindrical volume 408 within baseplate 412 that is at least a portion of the process volume, previously described as process volume 136 in FIG. 1 of a processing chamber 100. The cylindrical volume 408 and the interior surface 405 both have a diameter “D” between opposing points. For baseplate 412, there is also a uniform height “H” throughout. Using FIG. 4B, both the edges of the interior surface (line 405) at the view line as well as the interior surface (underlined 405) around the semi-circular surface in view, which also includes a view of substrate slot 413, is observed. At the point where reveal view AA occurs, an interior structure 409 of the baseplate 412 is revealed having a thickness of “Tb”, which represents the thickness of the baseplate at that view line. One of ordinary skill in the art appreciates that an embodiment baseplate also includes those with similar or different overall physical dimensions, such as, but not limited to, interior process volume circumference and diameter; baseplate thickness, width, and length; substrate slot dimensions and configurations, and number, position, and types of gas exhaust outlets, that are suitable for proper operation in what is appreciated as an epitaxial growth processing chamber.

In one or more embodiments, which may be combined with other embodiments, a baseplate is configured in a sandwich macrocell support structure configuration. As represented in FIG. 4B along view lines AA, the sandwich configuration 441 of the macrocell support structure 401 shows that there is a volume of interior structure 409 having a thickness Tb that is made of a macrocell support structure that is similar to sandwich macrocell support structure 241 of FIG. 2E. As viewed from FIG. 4A, the sandwich configuration 441 of the macrocell support structure 401 is visible, especially the region of macrocell support structure 401 in between a first plate 446 and a second plate 447. Although not literally shaped as “plates” in this instance, which may evoke an image of a flat surface, one of ordinary skill in the art appreciates that the lexicography is in keeping with the example of a sandwich macrocell support structure configuration previously described and associated with rectangle 240 in FIG. 2E, and is still applicable here and in other embodiments. Also shown in this instance is inlet fluid flow port 406 and outlet fluid flow port 407 to support the introduction and removal of cooling fluid through the interior of the freestanding macrocell support structure 401.

As seen in FIG. 4B, the entirety of macrocell support structure 401 is contained in between the first plate 446, which acts as the exterior-facing plate of baseplate 412, and the second plate 447, which acts as the interior-facing plate of baseplate 412. The first plate has a thickness (Te); the second plate has a thickness (Ti). In one or more embodiments, which may be combined with other embodiments, the thickness of the first plate (Te) is of about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, which may be combined with other embodiments, the thickness of the second plate (Ti) is of about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, which may be combined with other embodiments, the first and the second plates have the same or similar thickness. In one or more embodiments, which may be combined with other embodiments, the first plate has a greater thickness than the second plate. In one or more embodiments, which may be combined with other embodiments, the first plate has a lesser thickness than the second plate. Differences in the thicknesses between two plates occur for a variety of reasons, including, but not limited to, overall mechanical strength of the baseplate and safety and containment of the process fluid during operation. The thickness of the macrocell support structure would therefore be determined as the baseplate thickness (Tb) minus the sum of the two plate thicknesses (Ti+Te). One of ordinary skill in the art appreciates that the first and the second plate thicknesses change depending upon the viewing position and therefore vary in value from one value to another value within the range based upon position measured.

In such a macrocell support structure sandwich configuration, the interconnecting physical supports of the macrocell support structure are made of a metal. In one or more embodiments, which may be combined with other embodiments, first plate and the second plate are made of a metal. In one or more embodiments, which may be combined with other embodiments, the first plate and the second plate are both made of the same material as the interconnecting physical supports. That either or both the first plate and the second plate are made of a different metal material than the interconnecting physical supports is also contemplated.

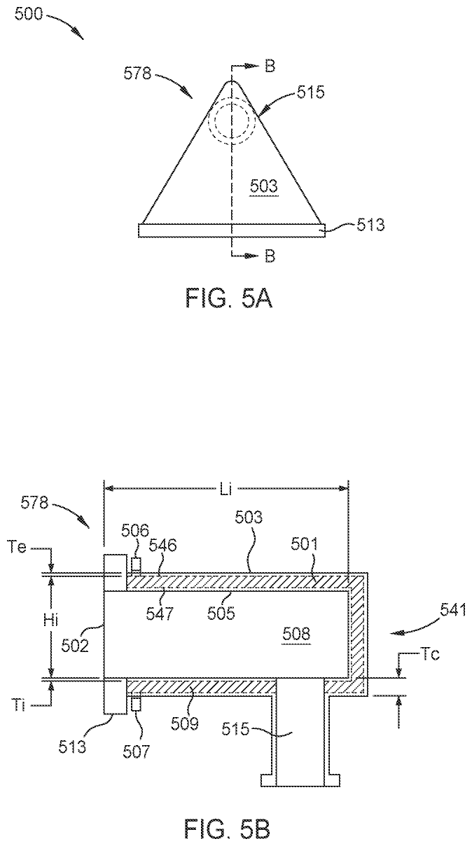

FIG. 5A is a schematic view 500 of an exhaust cap for an epitaxial growth processing chamber. FIG. 5B is a sectional view along line BB in FIG. 5A. In the reveal figure, entry port 502 is defined by coupling flange 513 and is usually in fluid communication with a process chamber, such as process chamber 100 when coupled or connected. The entry port 502 is fluidly accessible to interior 508, which is mostly defined by interior surface 505. Exterior surface 503 is visible in both FIGS. 5A and 5B as the top of the exhaust cap 578. There is also shown in FIG. 5B the interior structure 509 of exhaust cap 578. Outlet port 515 is fluidly accessible to interior 508 and permits gases to be discharged from the exhaust cap 578. Several dimensions are useful for describing aspects of embodiment exhaust caps. “Hi” is defined as the height between opposing points along the interior surface 505 of the lower and upper portions of the exhaust cap 578. “Li” is defined as the length or depth between the entry port 502 and an opposing side of the exhaust cap 578, such as along view line BB. “Tc” is the thickness of the surface of the exhaust cap 578, such as the thickness of interior structure 509. One of ordinary skill in the art appreciates that an embodiment exhaust cap also includes those with different overall physical dimensions, such as, but not limited to, thickness, width, height, volume, outlet port position and diameter, coupling or connectivity means to the baseplate, that are suitable for proper operation in what is appreciated as an epitaxial growth processing chamber.

Also shown in this instance is inlet fluid flow port 506 paired with an outlet fluid flow port 507 to support the introduction and removal of cooling fluid through the interior of the freestanding macrocell support structure 501.

In one or more embodiments, which may be combined with other embodiments, an exhaust cap is configured such that is in a macrocell support structure sandwich configuration. As represented in FIG. 5B along view lines BB, sandwich configuration 541 of the macrocell support structure 501 shows that there is a volume of interior structure 509 having a thickness Tc that is made of a macrocell support structure that is similar to sandwich macrocell support structure 241 of FIG. 2E. The region of macrocell support structure 501 in between a first plate 546 and a second plate 647.

As seen in FIG. 5B, the entirety of macrocell support structure 501 is contained in between the first plate 546, which acts as the exterior-facing plate of exhaust cap 578, and the second plate 547, which acts as the interior-facing plate of exhaust cap 578. The first plate has a thickness (Te); the second plate has a thickness (Ti). In one or more embodiments, which may be combined with other embodiments, the thickness of the first plate (Te) is of about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, which may be combined with other embodiments, the thickness of the second plate (Ti) is of about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, which may be combined with other embodiments, the first and the second plates have the same or similar thickness. In one or more embodiments, which may be combined with other embodiments, the first plate has a greater thickness than the second plate. In one or more embodiments, which may be combined with other embodiments, the first plate has a lesser thickness than the second plate. There may be differences in thicknesses between the two plates for a variety of reasons as previously described. The thickness of the macrocell support structure would therefore be determined as the exhaust cap thickness (Tc) minus the sum of the two plate thicknesses (Ti+Te). One of ordinary skill in the art appreciates that the first and the second plate thicknesses may change depending upon the viewing position and therefore vary in value from one value to another value within the range based upon position measured.

In such a macrocell support structure sandwich configuration, the interconnecting physical supports of the macrocell support structure are made of a metal. In one or more embodiments, which may be combined with other embodiments, the first plate and the second plate are made of a metal. In one or more embodiments, which may be combined with other embodiments, the first plate and the second plate are both made of the same material as the interconnecting physical supports. That either or both the first plate and the second plate are made of a different metal material than the interconnecting physical supports is contemplated.

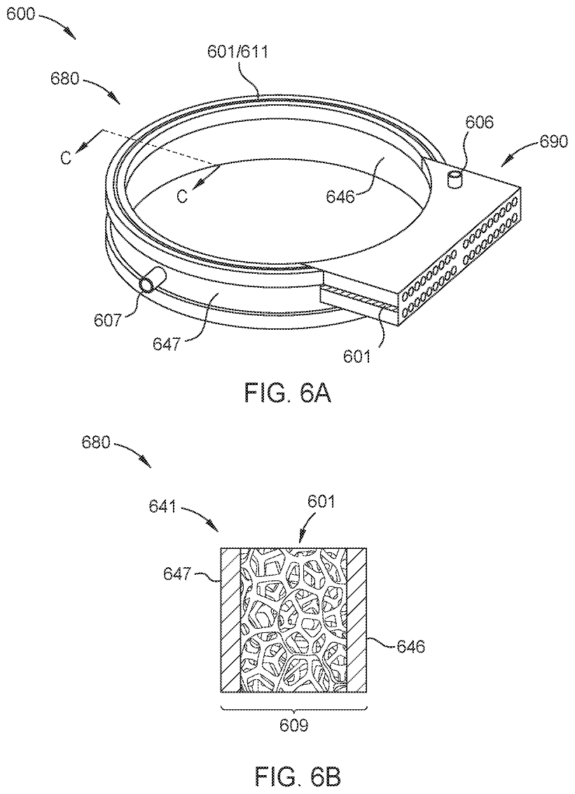

FIG. 6A is a schematic perspective view 600 of an injector ring. FIG. 6B is a schematic sectional view along line CC in FIG. 6A. As provided for in FIG. 6A, in one or more embodiments, which may be combined with other embodiments, a component including a macrocell support structure for use with an epitaxial growth processing chamber includes an injection ring, such as injection ring 680. Also provided for in FIG. 6A and shown coupled to injection ring 680, in one or more embodiments, which may be combined with other embodiments, a component including a macrocell support structure for use with an epitaxial growth processing chamber includes an injection cap, such as injection cap 690. Although an injection ring and an embodiment injection cap are shown in FIG. 6A, one of ordinary skill in the art appreciates that an embodiment of either the injection cap or the injection ring either have similar or different overall physical dimensions, such as, but not limited to, thickness, width, circumference, number of injection orifices, the manner and means by which injection cap and injection ring couple to one another or if they are a unitary piece, and diameter, that are suitable for proper operation in what is appreciated as an epitaxial growth processing chamber.

Also shown in this instance is an inlet fluid flow port 606 connected to the top of injection cap 690 and a paired outlet fluid flow port 607 connected to the side of injection ring 680. Having an inlet fluid flow port mounted on one component and an outlet fluid flow port mounted on a second component, where the two components share a common fluid flow pathway and are coupled, connected, or unitary, is envisioned to support the introduction and removal of cooling fluid through the interior of the freestanding macrocell support structure 601.

One or more macrocell support structure is useful for configuring an injection ring for use in an epitaxial growth processing chamber. In one or more embodiments, which may be combined with other embodiments, an injection ring is configured such that is in a macrocell support structure sandwich configuration. As represented in FIG. 6B along view lines CC, sandwich configuration 641 of the macrocell support structure 601 shows that there is a volume of interior structure 609 having a thickness that is made of a macrocell support structure that is similar to sandwich macrocell support structure 241 of FIG. 2E. In both FIGS. 6A and 6B, the sandwich configuration 641 of the macrocell support structure 601 is visible, especially the region of free-standing macrocell support structure 601 in between a first plate 646, which is the interior surface of the injection ring 680, and a second plate 647, which is the exterior surface of the injection ring 680.

As seen in FIG. 6B, the entirety of macrocell support structure 601 is contained in between the first plate 646, which acts as the interior-facing side, and the second plate 647, which acts as the exterior-facing side. The first plate has a thickness and the second plate has a thickness. In one or more embodiments, which may be combined with other embodiments, the thickness of the first plate is of about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, which may be combined with other embodiments, the thickness of the second plate is of about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, which may be combined with other embodiments, the first and the second plates have the same or similar thickness. In one or more embodiments, which may be combined with other embodiments, the first plate has a greater thickness than the second plate. In one or more embodiments, which may be combined with other embodiments, the first plate has a lesser thickness than the second plate. Differences in thicknesses between the two plates occur for a variety of reasons, including, but not limited to, overall mechanical strength of the baseplate and safety and containment of the process fluid during operation. The thickness of the macrocell support structure would therefore be determined as the injection ring thickness minus the sum of the two plate thicknesses. One of ordinary skill in the art appreciates that the first and the second plate thicknesses change depending upon the viewing position and therefore vary in value from one value to another value within the range based upon position measured.

In such a macrocell support structure sandwich configuration, the interconnecting physical supports of the macrocell support structure is made of a metal. In one or more embodiments, which may be combined with other embodiments, the first plate and the second plate are made of a metal. In one or more embodiments, which may be combined with other embodiments, the first plate and the second plate are both made of the same material as the interconnecting physical supports. That either or both the first plate and the second plate are made of a different metal material than the interconnecting physical supports is also contemplated.

Injection cap, such as injection cap 690 of FIG. 6A, has like features and aspects as the previously described injection ring, such as injection ring 680, including embodiment macrocell support structure configurations, compositions, and arrangements. This is to minimize the amount of difference in operation when both the injection ring and the inject cap are coupled or connected together for operation.

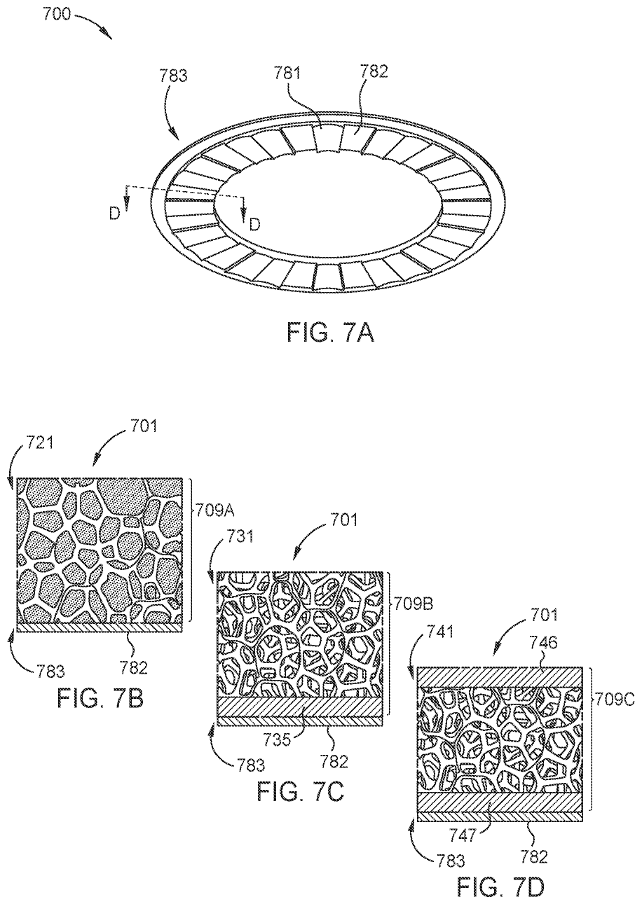

FIG. 7A is a schematic perspective view 700 of a reflector. FIGS. 7B, 7C, and 7D are each a schematic sectional view along line DD in FIG. 7A. In FIG. 7A, a reflector 783 is shown. In one or more embodiments, which may be combined with other embodiments, a component including an open microcell support structure for use with an epitaxial growth processing chamber includes a lamp reflector, such as a reflector with a concave reflecting surface 181 for the upper lamp module 155, a reflector with a flat reflecting surface 182 for the upper lamp module 155, a reflector with a concave reflecting surface 185 for the lower lamp module 145, and a reflector with a flat reflecting surface 186 for the lower lamp module 145 as shown in FIG. 1. In one or more embodiments, which may be combined with other embodiments, the reflector 783 is configured to be an upper reflector; in another one or more embodiments, the reflector 783 is configured to be a lower reflector. In one or more embodiments, which may be combined with other embodiments, a reflector 783 further includes a reflecting surface. In one or more embodiments, which may be combined with other embodiments, a reflecting surface is made of one or more of gold, alloys of gold, silver, alloys of silver, chromium, alloys of chromium, aluminum, alloys of aluminum, and combination thereof. Although an lamp reflector is shown in FIG. 7A appears to have both concave reflective surfaces 781 and flat reflective surfaces 782 interspersed, one of ordinary skill in the art appreciates that an embodiment lamp reflector also includes those with different overall physical dimensions, such as, but not limited to, thickness, internal and external circumferences, internal and external diameters, distribution of types of reflectors, angles of reflection, and degrees of concavity, that are suitable for proper operation in what is appreciated as an epitaxial growth processing chamber.

Although not shown for the sake of simplicity, in one or more embodiments, which may be combined with other embodiments, the reflector 783 is configured to have an inlet fluid flow port. In one or more embodiments, which may be combined with other embodiments, the reflector 783 is configured to have both an inlet fluid flow port and an outlet fluid flow port. In both instances, the two port configurations provide fluid connectivity to assist in driving a cooling fluid through an interior free-standing macrocell support structure.

There are one or more macrocell support structures that are useful for configuring a reflector for use in an epitaxial growth processing chamber. In one or more embodiments, which may be combined with other embodiments, a reflector 783 is configured such that is in a polymer-filled free-standing macrocell support structure configuration. In one or more embodiments, which may be combined with other embodiments, the lower reflector is configured in a polymer-filled free-standing macrocell support structure configuration. In one or more embodiments, which may be combined with other embodiments, the upper reflector is configured in a polymer-filled free-standing macrocell support structure configuration. As represented in FIG. 7B along view lines DD, polymer-filled free-standing macrocell support structure configuration 721 shows that there is a volume of interior structure 709A having a thickness that is made of a macrocell support structure 701 that is similar to polymer-filled free-standing macrocell support structure configuration 221 of FIG. 2C.

As seen in FIG. 7B, the entirety of macrocell support structure 701 is filled with a second solid material, which in FIG. 2C is second solid material 223. As shown in FIG. 7B, on the interior-facing side of the polymer-filled free-standing macrocell support structure 721 is a flat reflective surface 782. In one or more embodiments, which may be combined with other embodiments, the flat reflective surface are coupled or connected to the interior-facing side of the polymer-filled free-standing macrocell support structure. For example, a reflective surface is a mirror or a reflective film.

In such a polymer-filled free-standing macrocell support structure configuration, the interconnecting physical supports of the macrocell support structure is made of a metal. In one or more embodiments, which may be combined with other embodiments, the second solid material is made of a polymer.

In one or more embodiments, which may be combined with other embodiments, a reflector is configured such that is in a macrocell support structure plate-supported configuration. In one or more embodiments, which may be combined with other embodiments, the lower reflector is configured in a macrocell support structure plate-supported configuration; in one or more embodiments, which may be combined with other embodiments, the upper reflector is configured in a macrocell support structure plate-supported configuration. As represented in FIG. 7C along view lines DD, plate-supported macrocell support structure 731 shows that there is a volume of interior structure 709B having a thickness that is made of a macrocell support structure that is similar to plate-supported macrocell support structure configuration 231 of FIG. 2D.

As seen in FIG. 7C, the entirety of macrocell support structure 701 is supported by support plate 735, which acts as the interior-facing plate. The support plate 735 is directed inwards towards the process; the macrocell support structure is directed away from the process. As shown in FIG. 7C, on the exterior-facing side of the support plate 735 is a flat reflective surface 782. In one or more embodiments, the flat reflective surface is coupled or connected to the exterior side of the support plate. For example, the reflective surface 782 is a mirror or a reflective film. In one or more embodiments, which may be combined with other embodiments, the exterior-facing side of the support plate is configured such that the exterior-facing side has EM reflective properties, such as through a chemical treatment or mechanical polishing. In such an instance, the support plate and the reflective surface are one and the same; a unitary piece.

The support plate has a thickness. In one or more embodiments, which may be combined with other embodiments, the thickness of the support plate is of about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. The thicknesses of the support plate may vary for a variety of reasons, including, but not limited to, overall mechanical strength of the reflector and safety and containment of the process fluid during operation. The thickness of the macrocell support structure would therefore be determined as the reflector thickness minus the support plate thicknesses. One of ordinary skill in the art appreciates that the support plate thicknesses change depending upon the viewing position and therefore vary in value from one value to another value within the range based upon position measured.

In such a macrocell support structure plate-supported configuration, the interconnecting physical supports of the macrocell support structure is made of a metal. In one or more embodiments, support plate are made of a metal. In one or more embodiments, which may be combined with other embodiments, the support plate is made of the same material as the interconnecting physical supports. That either or both the support plate and the interconnecting physical supports are made of different metals is also contemplated.

In one or more embodiments, which may be combined with other embodiments, a reflector is configured such that is in a macrocell support structure sandwich configuration. In one or more embodiments, which may be combined with other embodiments, the lower reflector is configured in a macrocell support structure sandwich configuration; in one or more embodiments, which may be combined with other embodiments, the upper reflector is configured in a macrocell support structure sandwich configuration. As represented in FIG. 7D along view lines DD, sandwich configuration 741 of the macrocell support structure 701 shows that there is a volume of interior structure 709C having a thickness that is made of a macrocell support structure that is similar to sandwich macrocell support structure 241 of FIG. 2E.

As seen in FIG. 7D, the entirety of macrocell support structure 701 is contained in between a first plate 746, which acts as the exterior-facing plate, and a second plate 747, which acts as the interior-facing plate. The second plate 747 is directed inwards towards the process. For FIG. 7D, on the exterior-facing side of the second plate 747 a flat reflective surface 782 is present. In one or more embodiments, which may be combined with other embodiments, the flat reflective surface is coupled or connected to the exterior side of the second plate. For example, the reflective surface 782 is a mirror or a reflective film. In one or more embodiments, which may be combined with other embodiments, the exterior-facing side of the second plate is configured such that the exterior-facing side has EM reflective properties, such as through a chemical treatment or mechanical polishing. In such an instance, the second plate and the reflective surface is be one and the same; a unitary piece.

The first plate has a thickness and the second plate has a thickness. In one or more embodiments, which may be combined with other embodiments, the thickness of the first plate is of about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, which may be combined with other embodiments, the thickness of the second plate is of about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, which may be combined with other embodiments, the first and the second plates have the same or similar thickness. In one or more embodiments, which may be combined with other embodiments, the first plate has a greater thickness than the second plate. In one or more embodiments, which may be combined with other embodiments, the first plate has a lesser thickness than the second plate. Differences in thicknesses between the two plates exist for a variety of reasons, including, but not limited to, overall mechanical strength of the reflector and safety and containment of the process fluid during operation. The thickness of the macrocell support structure would therefore be determined as the reflector thickness minus the sum of the two plate thicknesses. One of ordinary skill in the art appreciates that the first and the second plate thicknesses change depending upon the viewing position and therefore vary in value from one value to another value within the range based upon position measured.

In such a macrocell support structure sandwich configuration, the interconnecting physical supports of the macrocell support structure is made of a metal. In one or more embodiments, which may be combined with other embodiments, the first plate and the second plate are made of a metal. In one or more embodiments, which may be combined with other embodiments, the first plate and the second plate are both made of the same material as the interconnecting physical supports. That either or both the first plate and the second plate are made of a different metal material than the interconnecting physical supports is also contemplated.

The lower and the upper reflector in one or more embodiments, which may be combined with other embodiments, have the same macrocell support structure configuration. In one or more embodiments, which may be combined with other embodiments, the lower and the upper reflector have different configurations. For a non-limiting example of the latter, the upper reflector is in a polymer-filled free-standing macrocell support structure configuration and the lower reflector is in a sandwich macrocell support structure configuration. As one of ordinary skill in the art appreciates, there are a number of technical or financial reasons for selecting a configuration for a given component that are unique to a given situation.

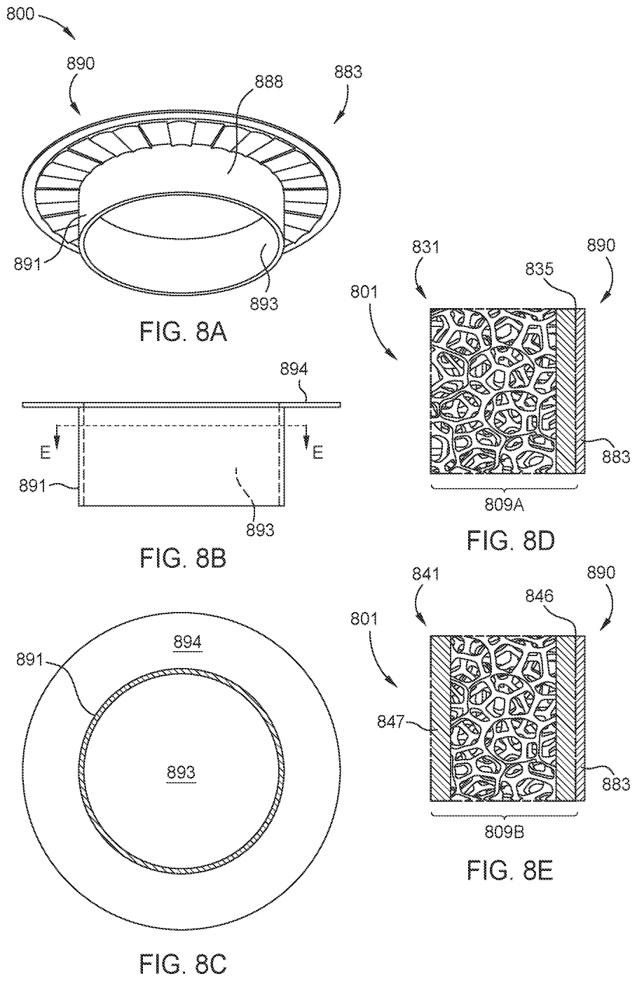

FIGS. 8A, 8B, and 8C are schematic perspective, side, and top-down views 800, respectively, of a heat shield. FIGS. 8D and 8E are each a schematic sectional view along line EE in FIG. 8B. In FIG. 8A, a heat shield 890 is shown. In one or more embodiments, which may be combined with other embodiments, a component including an open microcell support structure for use with an epitaxial growth processing chamber includes a heat shield, such as heat shield 890, which is similar to heat shield 190 for the upper lamp module 155 or heat shield 192 for the lower lamp module 145 as shown in FIG. 1. In one or more embodiments, which may be combined with other embodiments, the heat shield is configured as an upper heat shield; in another one or more embodiments, the heat shield is configured as a lower heat shield. A reflective surface 883, similar to the reflector 783 of FIG. 7A, is also shown in relation to heat shield 890 for this particular configuration. The embodiment heat shield 890 shown in FIG. 8A appears to have a reflector 888 positioned on the topside of base 894 along the outer surface of cylindrical shell body 891. In FIGS. 8A and 8C, heat shield interior 893 is defined by the interior surface of shell body 891. One of ordinary skill in the art appreciates that a heat shield also includes those with different overall physical dimensions and configurations, such as, but not limited to, having reflectors positioned within shaft hole, thicknesses of the cylindrical shell body, width of the base, circumference of the cylindrical shell body and the base, and respective diameter(s) that are suitable for proper operation in what is appreciated as an epitaxial growth processing chamber.

Although not shown for the sake of simplicity, in one or more embodiments, which may be combined with other embodiments, the reflector is configured to have an inlet fluid flow port. In one or more embodiments, which may be combined with other embodiments, the reflector is configured to have both an inlet fluid flow port and an outlet fluid flow port. In both instances, the two port configurations provide fluid connectivity to assist in driving a cooling fluid through an interior free-standing macrocell support structure.

There are one or more macrocell support structure that are useful for configuring a heat shield for use in an epitaxial growth processing chamber. In one or more embodiments, which may be combined with other embodiments, a heat shield is configured such that is in a macrocell support structure plate-supported configuration. In one or more embodiments, which may be combined with other embodiments, a lower heat shield is configured in a macrocell support structure plate-supported configuration. In one or more embodiments, which may be combined with other embodiments, an upper heat shield is configured in a macrocell support structure plate-supported configuration. As represented in FIG. 8D along view lines EE of FIG. 8B, plate-supported macrocell support structure 831 shows that there is a volume of interior structure 809A having a thickness that is made of a macrocell support structure that is similar to plate-supported macrocell support structure configuration 231 of FIG. 2D.

As seen in FIG. 8D, the entirety of macrocell support structure 801 is supported by support plate 835, which acts as the exterior-facing plate. The support plate 835 is directed inwards relative to the process; the macrocell support structure is directed away from the process. As shown in FIG. 8D, on the exterior-facing side of the support plate 835 is a reflective surface 883. In one or more embodiments, which may be combined with other embodiments, the reflective surface is coupled or connected to the exterior side of the support plate. For example, the reflective surface 883 is a mirror or a reflective film. In one or more embodiments, which may be combined with other embodiments, the exterior-facing side of the support plate is configured such that the exterior-facing side has EM reflective properties, such as through a chemical treatment or mechanical polishing. In such an instance, the support plate 835 and the reflective surface 883 are one and the same; a unitary piece.

The support plate has a thickness. In one or more embodiments, which may be combined with other embodiments, the thickness of the support plate is of about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. The thicknesses of the support plate varies for a variety of reasons, including, but not limited to, overall mechanical strength of the reflector and safety and containment of the process fluid during operation. The thickness of the macrocell support structure would therefore be determined as the reflector thickness minus the support plate thicknesses. One of ordinary skill in the art appreciates that the support plate thicknesses changes depending upon the viewing position and therefore vary in value from one value to another value within the range based upon position measured.

In such a macrocell support structure plate-supported configuration, the interconnecting physical supports of the macrocell support structure is made of a metal. In one or more embodiments, which may be combined with other embodiments, the support plate are made of a metal. In one or more embodiments, which may be combined with other embodiments, the support plate is made of the same material as the interconnecting physical supports. That either or both the support plate and the interconnecting physical is made of different materials is contemplated.

In one or more embodiments, which may be combined with other embodiments, a heat shield is configured such that is in a macrocell support structure sandwich configuration. In one or more embodiments, which may be combined with other embodiments, a lower heat shield is configured in a macrocell support structure sandwich configuration; in one or more embodiments, which may be combined with other embodiments, an upper heat shield is configured in a macrocell support structure sandwich configuration. As represented in FIG. 8E along view lines EE, sandwich configuration 841 of the macrocell support structure 801 shows that there is a volume of interior structure 809B having a thickness that is made of a macrocell support structure that is similar to sandwich macrocell support structure 241 of FIG. 2E.

As seen in FIG. 8E, the entirety of macrocell support structure 801 is contained in between a first plate 846, which acts as the exterior-facing plate, and a second plate 847, which acts as the interior-facing plate. The first plate 846 is directed inwards relative to the process. For FIG. 8E, on the exterior-facing side of the first plate 846 a reflective surface 883 is present. In one or more embodiments, which may be combined with other embodiments, a reflective surface is coupled or connected to the exterior side of the first plate. For example, the reflective surface 883 is a mirror or a reflective film. In one or more embodiments, which may be combined with other embodiments, the exterior-facing side of the first plate is configured such that the exterior-facing side has EM reflective properties, such as through a chemical treatment or mechanical polishing. In such an instance, the first plate and the reflective surface are one and the same; a unitary piece.

The first plate has a thickness and the second plate has a thickness. In one or more embodiments, which may be combined with other embodiments, the thickness of the first plate is of about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, which may be combined with other embodiments, the thickness of the second plate is of about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, which may be combined with other embodiments, the first and the second plates have the same or similar thickness. In one or more embodiments, which may be combined with other embodiments, the first plate has a greater thickness than the second plate. In one or more embodiments, which may be combined with other embodiments, the first plate has a lesser thickness than the second plate. Differences in thickness between the two plates occurs for a variety of reasons, including, but not limited to, overall mechanical strength of the reflector and safety and containment of the process fluid during operation. The thickness of the macrocell support structure would therefore be determined as the reflector thickness minus the sum of the two plate thicknesses. One of ordinary skill in the art appreciates that the first and the second plate thicknesses changes depending upon the viewing position and therefore vary in value from one value to another value within the range based upon position measured.

In such a macrocell support structure sandwich configuration, the interconnecting physical supports of the macrocell support structure is made of a metal. In one or more embodiments, which may be combined with other embodiments, the first plate and the second plate are made of a metal. In one or more embodiments, which may be combined with other embodiments, the first plate and the second plate are both made of the same material as the interconnecting physical supports. That the first plate and the second plate is either or both made of a different metal material than the interconnecting physical supports is contemplated.

The lower and the upper heat shields in one or more embodiments may have the same macrocell support structure configuration; in another one or more embodiments, the lower and the upper heat shields have different configurations. As one of ordinary skill in the art appreciates, there are a number of technical or financial reasons for selecting a configuration for a given component that are unique to a given situation.

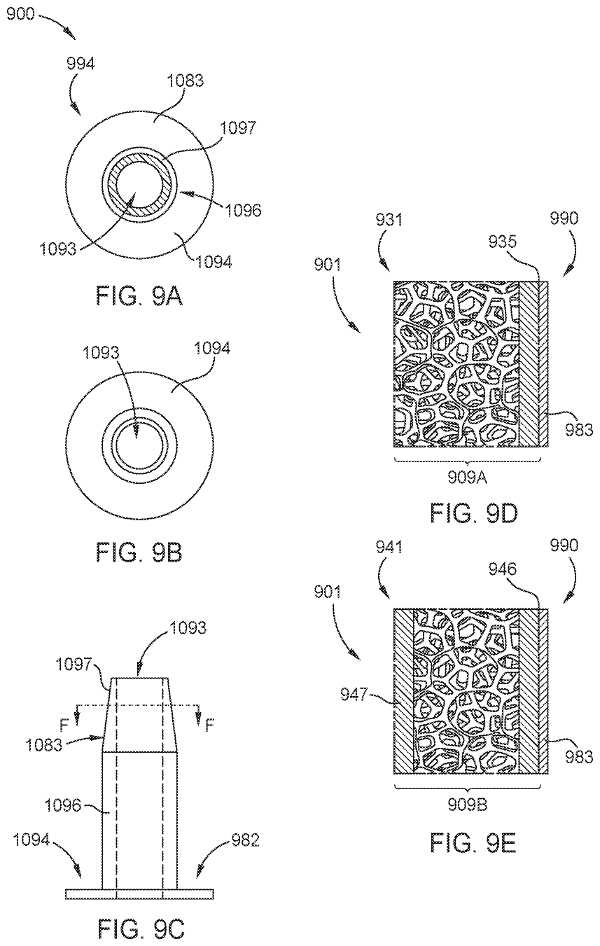

FIGS. 9A, 9B, and 9C are schematic drawings of a top-down, bottom-up, and side view 900, respectively, of a cone reflector. FIGS. 9D and 9E are each a schematic sectional view along line FF in FIG. 9C. In FIGS. 9A-C, a cone reflector is shown. In one or more embodiments, which may be combined with other embodiments, a component including an microcell support structure for use with an epitaxial growth processing chamber includes a cone reflector, such as cone reflector 994, which is similar to cone reflector 194 as shown in FIG. 1. Cone reflector has a base 1094 that has on its upper surface a flat reflecting surface 982 for reflecting EM irradiation upwards into the epitaxial growth processing chamber. Exterior facing sides of the neck 1096 and top 1097 reflect EM irradiation back into the epitaxial growth processing chamber. The top 1097, neck 1096, and the base 1094 define along their interior surfaces a shaft hole 1093 through which a portion of lower window, such as lower window 110 as shown in FIG. 1, passes. Although an embodiment cone reflector shown in FIGS. 9A-C appears to be a combination of both a heat shield and a reflector, one of ordinary skill in the art appreciates that an embodiment “cone reflector” is either or both a heat shield and a reflector, and embodiments also include those with different overall physical dimensions and configurations, such as, but not limited to, having only on a portion of the exterior surface that is reflective, various heights and shapes of the neck and the top, and various diameter of the base, that are suitable for proper operation in what is appreciated as an epitaxial growth processing chamber.

Although not shown for the sake of simplicity, in one or more embodiments, which may be combined with other embodiments, the cone reflector is configured to have an inlet fluid flow port. In one or more embodiments, which may be combined with other embodiments, the cone reflector is configured to have both an inlet fluid flow port and an outlet fluid flow port. In both instances, the two port configurations provide fluid connectivity to assist in driving a cooling fluid through an interior free-standing macrocell support structure.

There are one or more macrocell support structure that are useful for configuring a cone reflector for use in an epitaxial growth processing chamber. In one or more embodiments, which may be combined with other embodiments, a cone reflector is configured such that is in a macrocell support structure plate-supported configuration. In one or more embodiments, which may be combined with other embodiments, a cone reflector is configured in a macrocell support structure plate-supported configuration; in one or more embodiments, which may be combined with other embodiments, an upper heat shield is configured in a macrocell support structure plate-supported configuration. As represented in FIG. 8D along view lines FF of FIG. 9C, plate-supported macrocell support structure 931 shows that there is a volume of interior structure 909A having a thickness that is made of a macrocell support structure that is similar to plate-supported macrocell support structure configuration 231 of FIG. 2D.

As seen in FIG. 9D, the entirety of macrocell support structure 901 is supported by support plate 935, which acts as the interior-facing plate. The support plate 935 is directed inwards towards the process; the macrocell support structure is directed towards the shaft hole 1093. As shown in FIG. 9D, on the exterior-facing side of the support plate 935 is a reflective surface 983. In one or more embodiments, which may be combined with other embodiments, the reflective surface may be coupled or connected to the exterior side of the support plate. For example, the reflective surface is mirror or a reflective film. In one or more embodiments, which may be combined with other embodiments, the exterior-facing side of the support plate is configured such that the exterior-facing side has EM reflective properties, such as through a chemical treatment or mechanical polishing. In such an instance, the support plate and the reflective surface is one and the same; a unitary piece.

The support plate has a thickness. In one or more embodiments, which may be combined with other embodiments, the thickness of the support plate is of about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. The thickness of the support plate varies for a variety of reasons, including, but not limited to, overall mechanical strength of the reflector and safety and containment of the process fluid during operation. The thickness of the macrocell support structure would therefore be determined as the reflector thickness minus the support plate thicknesses. One of ordinary skill in the art appreciates that the support plate thickness changes depending upon the viewing position and therefore varies in value from one value to another value within the range based upon position measured.

In such a macrocell support structure plate-supported configuration, the interconnecting physical supports of the macrocell support structure is made of a metal. In one or more embodiments, which may be combined with other embodiments, support plate are made of a metal. In one or more embodiments, which may be combined with other embodiments, the support plate is made of the same material as the interconnecting physical supports. That the support plate and the interconnecting physical supports are either or both made of a different metal material is contemplated.

In one or more embodiments, which may be combined with other embodiments, a cone reflector is configured such that is in a macrocell support structure sandwich configuration. As represented in FIG. 9E along view lines FF, sandwich configuration 941 of the macrocell support structure 901 shows that there is a volume of interior structure 909B having a thickness that is made of a macrocell support structure that is similar to sandwich macrocell support structure 241 of FIG. 2E.

As seen in FIG. 9E, the entirety of macrocell support structure 901 is contained in between a first plate 946, which acts as the interior-facing plate, and a second plate 947, which acts as the exterior-facing plate. The first plate 946 is directed towards the process side; the second plate is directed towards the shaft hole 1093. For FIG. 9E, on the exterior-facing side of the first plate 946 a reflective surface 983 is present. In one or more embodiments, which may be combined with other embodiments, a reflective surface is coupled or connected to the exterior side of the first plate. For example, the reflective surface 983 is a mirror or a reflective film. In one or more embodiments, which is combined with other embodiments, the exterior-facing side of the first plate is configured such that the exterior-facing side has EM reflective properties, such as through a chemical treatment or mechanical polishing. In such an instance, the first plate and the reflective surface is one and the same; a unitary piece.

The first plate has a thickness and the second plate has a thickness. In one or more embodiments, which may be combined with other embodiments, the thickness of the first plate is of about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, which may be combined with other embodiments, the thickness of the second plate is of about 0.05 to about 5 mm, such as from 0.05, 0.07, 0.1, 0.2, 0.3, 0.5, 0.7, 0.9, and 1.0 to about 1.5, 2.0, 2.5, 3.0, 3.5, 4.0, 4.5, and 5.0 millimeters (mm), including all range combinations and end points inclusive. In one or more embodiments, which may be combined with other embodiments, the first and the second plates have the same or similar thickness. In one or more embodiments, which may be combined with other embodiments, the first plate has a greater thickness than the second plate. In one or more embodiments, which may be combined with other embodiments, the first plate has a lesser thickness than the second plate. Differences in thickness between the two plates occur for a variety of reasons, including, but not limited to, overall mechanical strength of the reflector and safety and containment of the process fluid during operation. The thickness of the macrocell support structure would therefore be determined as the reflector thickness minus the sum of the two plate thicknesses. One of ordinary skill in the art appreciates that the thickness of the first and the second plate changes depending upon the viewing position and therefore varies in value from one value to another value within the range based upon position measured.

As is appreciated by one of ordinary skill in the art, one or more other components of the epitaxial growth processing chamber is configured with configurations using one, some, or all of the macrocell support structures in the various forms described. As well, alternative configurations of the open microcell support structures are also contemplated and envisioned.

In one or more embodiments, which may be combined with other embodiments, an epitaxial growth processing chamber may include a component having a macrocell support structure that is configured with interconnecting physical supports that define one or more fluidly-connected pores and an inlet fluid flow port configured to provide fluid communication between the macrocell support structure and an exterior of the epitaxial growth processing chamber.

In one or more embodiments, which may be combined with other embodiments, the component of the epitaxial growth processing chamber is a baseplate, an exhaust cap, an injection ring, an injection cap, a lower reflector, an upper reflector, a lower heat shield, an upper heat shield, a cone reflector, or combinations thereof.

In one or more embodiments, which may be combined with other embodiments, the interconnecting physical supports of the macrocell support structure of the component of the epitaxial growth processing chamber includes a metal, a ceramic or glass material, a polymeric material, or a combination thereof.

In one or more embodiments, which may be combined with other embodiments, the macrocell support structure of the component is configured with a porosity of about 70% to about 98% of the volume of the macrocell support structure.

In one or more embodiments, which may be combined with other embodiments, the macrocell support structure of the component of the epitaxial growth processing chamber has pores that are configured with an average pore size of about 20 microns to about 5000 microns.

In one or more embodiments, which may be combined with other embodiments, the macrocell support structure of the component of the epitaxial growth processing chamber is configured to have a permeability of about 70% to about 100% of the pores of the macrocell support structure.

In one or more embodiments, which may be combined with other embodiments, the configuration of the macrocell support structure of the component is a free-standing macrocell support structure configuration, a plate-supported macrocell support structure configuration, a sandwich macrocell support structure configuration, a surface sealed macrocell support structure configuration, and a solid polymer-filled macrocell support structure configuration, or combinations thereof.

In one or more embodiments, which may be combined with other embodiments, the component of the epitaxial growth processing chamber is in a unitary configuration.

In one or more embodiments, which may be combined with other embodiments, the component of the epitaxial growth processing chamber further includes both an outlet fluid flow port configured to provide fluid communication between the macrocell support structure and the exterior and a fluid flow wall.

In one or more embodiments, which may be combined with other embodiments, the component of the epitaxial growth processing chamber further includes a fluid flow baffle.

In one or more embodiments, which may be combined with other embodiments, the component of the epitaxial growth processing chamber includes a reflective surface.

In one or more embodiments, which may be combined with other embodiments, the component having a solid polymer-filled macrocell support structure configuration further includes a thermoset polymer, poly(ethyl ether ketone) (PEEK), a polyimide, or combinations thereof.

In one or more embodiments, which may be combined with other embodiments, the component having the plate-supported configuration includes a support plate including a similar material to that of than the interconnecting physical supports.

In one or more embodiments, which may be combined with other embodiments, the component in the sandwich configuration includes a first plate and a second plate. Each plate includes a similar material to that of the interconnecting physical supports.

In one or more embodiments, which may be combined with other embodiments, the component in the sandwich configuration includes a first plate and a second plate. The first plate and the second plate each includes a different material to the other.

In one or more embodiments, which may be combined with other embodiments, a component configured for use in a an epitaxial growth processing chamber has a macrocell support structure that is configured with interconnecting physical supports that define one or more fluidly-connected pores and an inlet fluid flow port configured to provide fluid communication between the macrocell support structure and an exterior of the component.

In one or more embodiments, which may be combined with other embodiments, the component is a baseplate, an exhaust cap, an injection ring, an injection cap, a lower reflector, an upper reflector, a lower heat shield, an upper heat shield, a cone reflector, or combinations thereof.

In one or more embodiments, which may be combined with other embodiments, the interconnecting physical supports of the macrocell support structure of the component includes a metal, a ceramic or glass material, a polymeric material, or a combination thereof.

In one or more embodiments, which may be combined with other embodiments, the macrocell support structure of the component is configured with a porosity of about 70% to about 98% of the volume of the macrocell support structure.

In one or more embodiments, which may be combined with other embodiments, the macrocell support structure of the component has pores that are configured with an average pore size of about 20 microns to about 5000 microns.

In one or more embodiments, which may be combined with other embodiments, the macrocell support structure of the component is configured to have a permeability of about 70% to about 100% of the pores of the macrocell support structure.

In one or more embodiments, which may be combined with other embodiments, the configuration of the macrocell support structure of the component is a free-standing macrocell support structure configuration, a plate-supported macrocell support structure configuration, a sandwich macrocell support structure configuration, a surface sealed macrocell support structure configuration, and a solid polymer-filled macrocell support structure configuration, or combinations thereof.

In one or more embodiments, which may be combined with other embodiments, the component is in a unitary configuration.

In one or more embodiments, which may be combined with other embodiments, the component further includes both an outlet fluid flow port configured to provide fluid communication between the macrocell support structure and an exterior of the component and a fluid flow wall.

In one or more embodiments, which may be combined with other embodiments, the component further includes a fluid flow baffle.

In one or more embodiments, which may be combined with other embodiments, the component includes a reflective surface.

In one or more embodiments, which may be combined with other embodiments, the component having a solid polymer-filled macrocell support structure configuration further includes a thermoset polymer, poly(ethyl ether ketone) (PEEK), a polyimide, or combinations thereof.

In one or more embodiments, which may be combined with other embodiments, the component having the plate-supported configuration includes a support plate including a similar material to that of than the interconnecting physical supports.

In one or more embodiments, which may be combined with other embodiments, the component in the sandwich configuration includes a first plate and a second plate. Each plate includes a similar material to that of the interconnecting physical supports.

In one or more embodiments, which may be combined with other embodiments, the component in the sandwich configuration includes a first plate and a second plate. The first plate and the second plate each includes a different material to the other.

While this specification contains many specific implementation details, these should not be construed as limitations on the scope of what can be claimed, but rather as descriptions of features that can be specific to particular implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features can be described as acting in certain combinations and even initially claimed as such, one or more features from a claimed combination can, in some cases, be excised from the combination, and the claimed combination can be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations may be considered optional) to achieve desirable results. In certain circumstances, multitasking or parallel processing (or a combination of multitasking and parallel processing) can be advantageous and performed as deemed appropriate.

Moreover, the separation or integration of various system modules and components in the previously described implementations should not be understood as requiring such separation or integration in all implementations. It should be understood that the described program components and systems can generally be integrated together in a single software product or packaged into multiple software products.

Accordingly, the previously described example implementations do not define or constrain the present disclosure. Other changes, substitutions, and alterations are also possible without departing from the spirit and scope of the present disclosure.

While the various steps in an embodiment method or process are presented and described sequentially, one of ordinary skill in the art will appreciate that some or all of the steps may be executed in different order, may be combined or omitted, and some or all of the steps may be executed in parallel. The steps may be performed actively or passively. The method or process may be repeated or expanded to support multiple components or multiple users within a field environment. Accordingly, the scope should not be considered limited to the specific arrangement of steps shown in a flowchart or diagram.

Unless defined otherwise, all technical and scientific terms used have the same meaning as commonly understood by one of ordinary skill in the art to which these systems, apparatuses, methods, processes and compositions belong.

The singular forms “a,” “an,” and “the” include plural referents, unless the context clearly dictates otherwise. Within a claim, reference to an element in the singular is not intended to mean “one and only one” unless specifically so stated, but rather “one or more.” Unless specifically stated otherwise, the term “some” refers to one or more.

Embodiments of the present disclosure may suitably “comprise”, “consist” or “consist essentially of” the limiting features disclosed, and may be practiced in the absence of a limiting feature not disclosed. As used here and in the appended claims, the words “comprise,” “has,” and “include” and all grammatical variations thereof are each intended to have an open, non-limiting meaning that does not exclude additional elements or steps.

“Optional” and “optionally” means that the subsequently described material, event, or circumstance may or may not be present or occur. The description includes instances where the material, event, or circumstance occurs and instances where it does not occur.

As used, the term “determining” encompasses a wide variety of actions. For example, “determining” may include calculating, computing, processing, deriving, investigating, looking up (for example, looking up in a table, a database or another data structure), and ascertaining. Also, “determining” may include receiving (for example, receiving information) and accessing (for example, accessing data in a memory). Also, “determining” may include resolving, selecting, choosing, and establishing.

When the word “approximately” or “about” are used, this term may mean that there can be a variance in value of up to +10%, of up to 5%, of up to 2%, of up to 1%, of up to 0.5%, of up to 0.1%, or up to 0.01%.

Ranges may be expressed as from about one particular value to about another particular value, inclusive. When such a range is expressed, it is to be understood that another embodiment is from the one particular value to the other particular value, along with all particular values or combinations thereof within the range.

As used, terms such as “first” and “second” are arbitrarily assigned and are merely intended to differentiate between two or more components of a system, an apparatus, or a composition. It is to be understood that the words “first” and “second” serve no other purpose and are not part of the name or description of the component, nor do they necessarily define a relative location or position of the component. Furthermore, it is to be understood that that the mere use of the term “first” and “second” does not require that there be any “third” component, although that possibility is contemplated under the scope of the various embodiments described.

Although only a few example embodiments have been described in detail, those skilled in the art will readily appreciate that many modifications are possible in the example embodiments without materially departing from the disclosed scope as described. Accordingly, all such modifications are intended to be included within the scope of this disclosure as defined in the following claims. In the claims, means-plus-function clauses are intended to cover the structures described as performing the recited function and not only structural equivalents, but also equivalent structures. For example, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112(f), for any limitations of any of the claims, except for those in which the claim expressly uses the words ‘means for’ together with an associated function.

The following claims are not intended to be limited to the embodiments provided but rather are to be accorded the full scope consistent with the language of the claims.

What is claimed is:

1. An epitaxial growth processing chamber, comprising:
a component comprising:
a macrocell support structure comprising interconnecting physical supports defining fluidly-connected pores; and
an inlet fluid flow port configured to provide fluid communication between the macrocell support structure and an exterior of the epitaxial growth processing chamber.

2. The epitaxial growth processing chamber of claim 1, wherein the component is a baseplate, an exhaust cap, an injection ring, an injection cap, a lower reflector, an upper reflector, a lower heat shield, an upper heat shield, a cone reflector, or combinations thereof.

3. The epitaxial growth processing chamber of claim 1, wherein the interconnecting physical supports of the macrocell support structure of the component comprise a metal, a ceramic or glass material, a polymeric material, or combinations thereof.

4. The epitaxial growth processing chamber of claim 1, wherein the macrocell support structure of the component has a porosity of about 70% to about 98% of a volume of the macrocell support structure.

5. The epitaxial growth processing chamber of claim 1, wherein the pores of the macrocell support structure of the component are configured with an average pore size of about 20 microns to about 5000 microns.

6. The epitaxial growth processing chamber of claim 1, wherein the macrocell support structure of the component is configured with a permeability of about 70% to about 100% of the pores of the macrocell support structure.

7. The epitaxial growth processing chamber of claim 1, wherein the configuration of the macrocell support structure of the component is a free-standing macrocell support structure configuration, a plate-supported macrocell support structure configuration, a sandwich macrocell support structure configuration, a surface sealed macrocell support structure configuration, or a solid polymer-filled macrocell support structure configuration.

8. The epitaxial growth processing chamber of claim 7, wherein the component is a unitary component.

9. The epitaxial growth processing chamber of claim 1, wherein the component further comprises an outlet fluid flow port and a fluid flow wall.

10. The epitaxial growth processing chamber of claim 9, wherein the component further comprises a fluid flow baffle.

11. The epitaxial growth processing chamber of claim 1, wherein the component further comprises a reflective surface.

12. The epitaxial growth processing chamber of claim 1, wherein the component is in a solid polymer-filled macrocell support structure configuration that comprises a thermoset polymer, poly(ethyl ether ketone) (PEEK), a polyimide, or combinations thereof.

13. The epitaxial growth processing chamber of claim 1, wherein the component is in a plate-supported configuration that includes a support plate comprising a similar material to that of than the interconnecting physical supports.

14. The epitaxial growth processing chamber of claim 1, wherein the component is in a sandwich configuration that includes a first plate comprising a first material and a second plate comprising a second material, wherein each of the first material and the second material are a similar material to that of the interconnecting physical supports.

15. The epitaxial growth processing chamber of claim 1, wherein the component is in a sandwich configuration that includes a first plate comprising a first material and a second plate comprising a second material, and wherein the first material and the second material are different.

16. A component configured for use in an epitaxial growth processing chamber, comprising:
a macrocell support structure comprising interconnecting physical supports defining fluidly-connected pores; and
an inlet fluid flow port configured to provide fluid communication between the macrocell support structure and an exterior of the component.

17. The component of claim 16, wherein the component is a baseplate, an exhaust cap, an injection ring, an injection cap, a lower reflector, an upper reflector, a lower heat shield, an upper heat shield, a cone reflector, or combinations thereof.

18. The component of claim 16, wherein the configuration of the macrocell support structure of the component is a free-standing macrocell support structure configuration, a plate-supported macrocell support structure configuration, a sandwich macrocell support structure configuration, a surface sealed macrocell support structure configuration, or a solid polymer-filled macrocell support structure configuration.

19. A component configured for use in an epitaxial growth processing chamber, comprising:
a macrocell support structure comprising interconnecting physical supports defining fluidly-connected pores;
an inlet fluid flow port configured to provide fluid communication between the macrocell support structure and an exterior of the component; and,
an outlet fluid flow port configured to provide fluid communication between the macrocell support structure and an exterior of the component and a fluid flow wall.

20. The component of claim 19, wherein the component further comprises a fluid flow baffle.
